(19) United States
(12) Patent Application Publication
(10) Pub. No.: US 2007/0044833 A1
(43) Pub. Date: Mar. 1, 2007

(54) Solar energy collector and array of the same

(75) Inventors: Jyh Long Chern, Hsin-Chu (TW); Yen Chang Tzeng, Taoyuan (TW); Hwen Fen Hong, Taoyuan (TW); Jain Cheng Chen, Hsin-Chu (TW); Chia Yu Hu, Hsin-Chu (TW); Hung Zen Kuo, Taoyuan (TW); Hwa Yuh Shin, Taoyuan (TW)

Correspondence Address: EGBERT LAW OFFICES, 412 MAIN STREET, 7TH FLOOR, HOUSTON, TX, 77002, US

(73) Assignee: ATOMIC ENERGY COUNCIL - INSTITUTE OF NUCLEAR ENERGY RESEARCH, Taoyuan (TW)

(21) Appl. No.: 11/317,628

(22) Filed: Dec. 23, 2005

(30) Foreign Application Priority Data
Aug. 24, 2005 (TW) 094128891

(51) Int. Cl. H01L 31/00

(52) U.S. Cl. 136/259

(57) ABSTRACT

The present solar energy collector includes a substrate and a plurality of plates assembled on the substrate in a roof manner, wherein the plates include a plurality of protrusions capable of collecting a penetrating solar ray on a solar cell positioned at a predetermined region on the substrate. The solar energy collector may include two trapezoid plates and two triangular plates assembled on the substrate in an inclined manner to form a hip-roof. The solar energy collector may include four trapezoid plates positioned on the substrate in an inclined manner and one rectangular plate positioned on the trapezoid plates to form a mansard roof. The solar energy collector may include six first rectangular plates positioned on the substrate in a hexagonal manner, six second rectangular plates positioned on the first rectangular plates, and a hexagonal plate positioned on the second rectangular plates.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The present invention relates to a solar energy collector and the array of the same, and more particularly, to a solar energy collector comprising a plurality of planar plates assembled in a roof manner and the array of the same.

### BACKGROUND OF THE INVENTION

As industry is experiencing rapid growth, petroleum exhaust and the discharge of greenhouse gases from the use of petroleum are getting more and more attention. Nowadays, researchers try to find an alternative energy to petroleum to achieve a stable energy supply. Compared with conventional energy such as coal or nuclear energy, a solar cell uses the photoelectric effect to transform solar energy into electrical energy, which does not generate polluting gases or greenhouse gases such as carbon dioxide, nitrogen oxide or sulfur oxide. Particularly, the solar cell can supply stable and safe electrical energy to decrease the use of petroleum.

U.S. Pat. No. 4,057,048 discloses a solar heat concentrator, which uses a dome-shaped lens to collect solar energy. U.S. Pat. No. 4,256,088 discloses a solar concentrator including a concentrating panel, which has an overall parabolic reflecting surface. U.S. Pat. No. 4,513,731 discloses a solar heat collector using a Fresnel lens to collect solar energy. A conventional solar energy concentrator uses a dome-shaped non-planar lens to collect light beams from any angle due to the movement of the sun. However, the fabrication of the non-planar lens is very difficult, and the cost is therefore very expensive. Particularly, to fabricate protrusion patterns that are different from each other on a glass substrate is much more difficult. Since the conventional dome-shaped Fresnel lens is difficult to fabricate, its cost is expensive, and it is difficult for it to have a wide application.

### BRIEF SUMMARY OF THE INVENTION

The objective of the present invention is to provide a solar energy collector comprising a plurality of plates assembled in a roof manner and the array of the same, which possesses a lower cost and can collect omni-directional light beams.

In order to achieve the above-mentioned objective and avoid the problems of the prior art, one embodiment of the present invention discloses a solar energy collector comprising a substrate and a plurality of plates assembled on the substrate in the form of a roof. The plates include a plurality of protrusions capable of refracting light beams that penetrate through the plates to a solar cell positioned on the substrate. The solar energy collector may include two trapezoid plates and two triangular plates positioned on the substrate in a symmetrically inclined manner to form a hip roof. In addition, the solar energy collector may include four trapezoid plates positioned on the substrate in an inclined manner and a rectangular plate positioned on the trapezoid plates to form a mansard roof. Further, the solar energy collector may include six first rectangular plates positioned on the substrate in an inclined manner, six second rectangular plates positioned on the first rectangular plates in an inclined manner and a hexagonal plate positioned on the second rectangular plates.

Another embodiment of the present invention discloses a solar energy collector array comprising a substrate and a plurality of collecting units positioned on the substrate in an array manner. The collecting unit includes a plurality of plates assembled in a roof manner, and the plates include a plurality of protrusions capable of refracting light beams that penetrate through the plates to a solar cell positioned in the collecting unit.

The conventional dome-shaped Fresnel lens is difficult to fabricate, its cost is expensive, and it is difficult for it to have a wide application. On the contrary, the present invention uses a planar plate having protrusion patterns to form a solar energy collector in a roof manner, which possesses a lower cost and can collect omni-directional light beams. Compared to the expensive fabrication of the conventional dome-shaped Fresnel lens, the fabrication cost of the present planar plate is much lower since it is planar. In addition, the present invention assembles the planar plate in a roof manner; therefore the collector can collect omni-directional light beams penetrating therethrough.

### BRIEF DESCRIPTION OF THE SEVERAL VIEWS OF THE DRAWINGS

The objectives and advantages of the present invention will become apparent upon reading the following description and upon reference to the accompanying drawings.

FIG. 1 and FIG. 2 illustrate perspective and elevation views of a solar energy collector according to a first embodiment of the present invention.

FIG. 3 illustrates perspective view of a solar energy collector according to a second embodiment of the present invention.

FIG. 4 illustrates another perspective view of a solar energy collector according to a third embodiment of the present invention.

FIG. 5 illustrates perspective view of a solar energy collector according to a fourth embodiment of the present invention.

FIG. 6 illustrates another perspective view of a solar energy collector array according to a first embodiment of the present invention.

FIG. 7 illustrates perspective view of a solar energy collector array according to a second embodiment of the present invention.

### DETAILED DESCRIPTION OF THE INVENTION

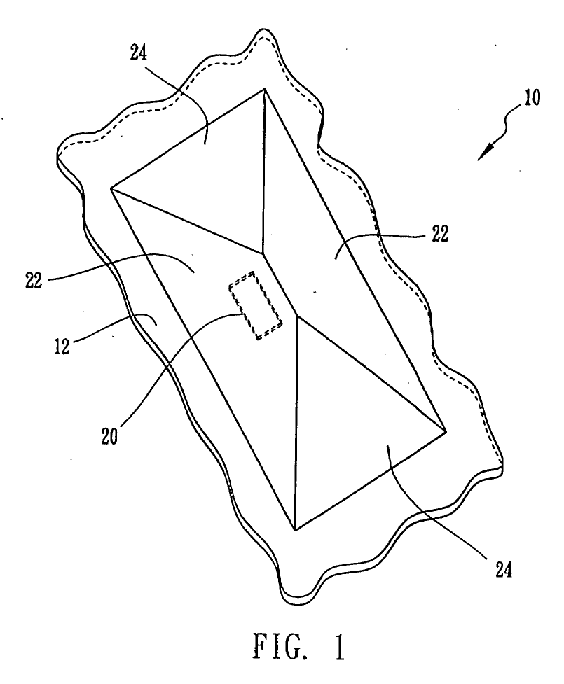

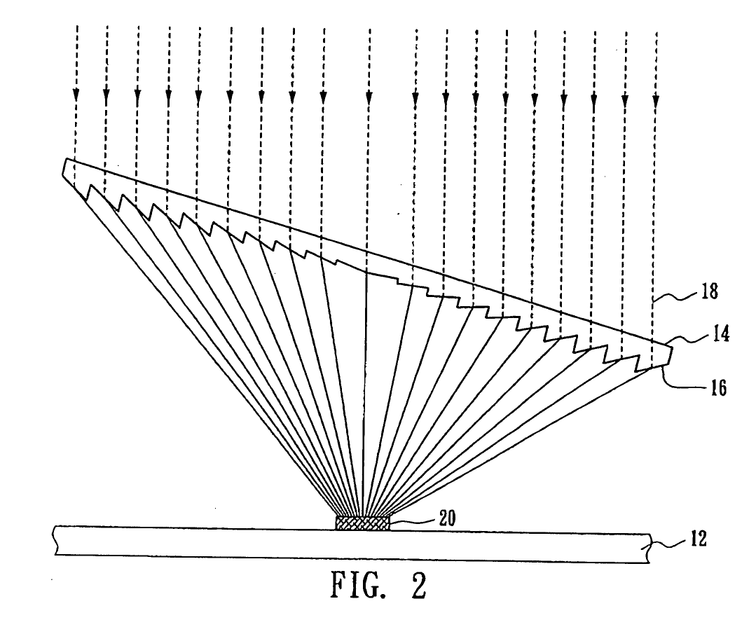

FIG. 1 and FIG. 2 illustrate a solar energy collector 10 according to a first embodiment of the present invention. The solar energy collector 10 comprises a substrate 12, two trapezoid plates 22, and two triangular plates 24 assembled on the substrate as a hip roof. Particularly, the trapezoid plates 22 and the triangular plates 24 are positioned on the substrate 12 in a symmetrically inclined manner, and the assembly of these plates can use fasteners such as bolts and nuts. The trapezoid plates 22 and the triangular plates 24 have a plurality of saw-toothed protrusions 16, i.e., light-collecting patterns, which are capable of refracting light beams 18 that penetrate through the trapezoid plates 22 and the triangular plates 24 to a solar cell 20 positioned on the substrate 12, as shown in FIG. 2. In other words, the protrusion 16 can collect light beams 18 that penetrate through the trapezoid plates 22 and the triangular plates 24 on a solar cell 20 positioned on the substrate 12.

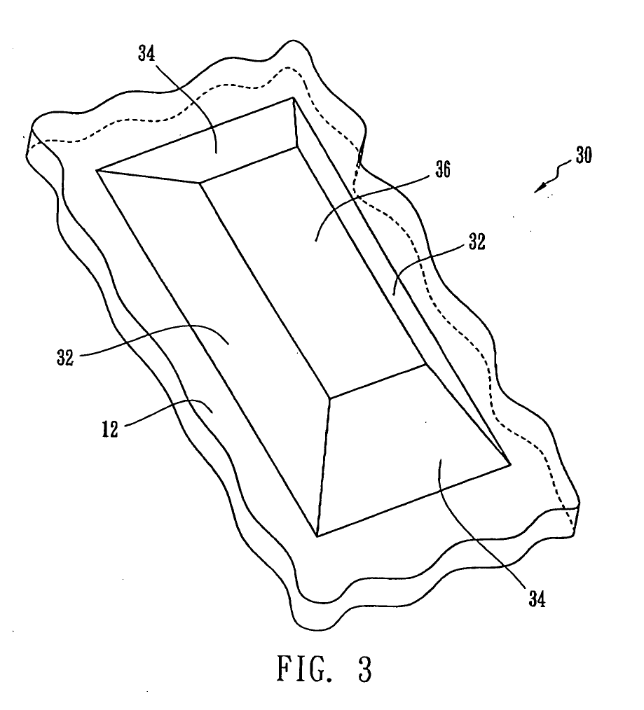

FIG. 3 illustrates a solar energy collector 30 as a mansard roof according to a second embodiment of the present invention. The solar energy collector 30 includes two trapezoid plates 32, two trapezoid plates 34, and one rectangular plate 36 positioned on the substrate 12 in a symmetrically inclined manner. For example, the trapezoid plates 32, 34 may have several supporting beams protruding inward (not shown in the drawings), and the rectangular plate 36 can be positioned on the supporting beams, i.e., the periphery of the rectangular plate 36 can be positioned on the supporting beams on the upper edge of the trapezoid plates 32, 34.

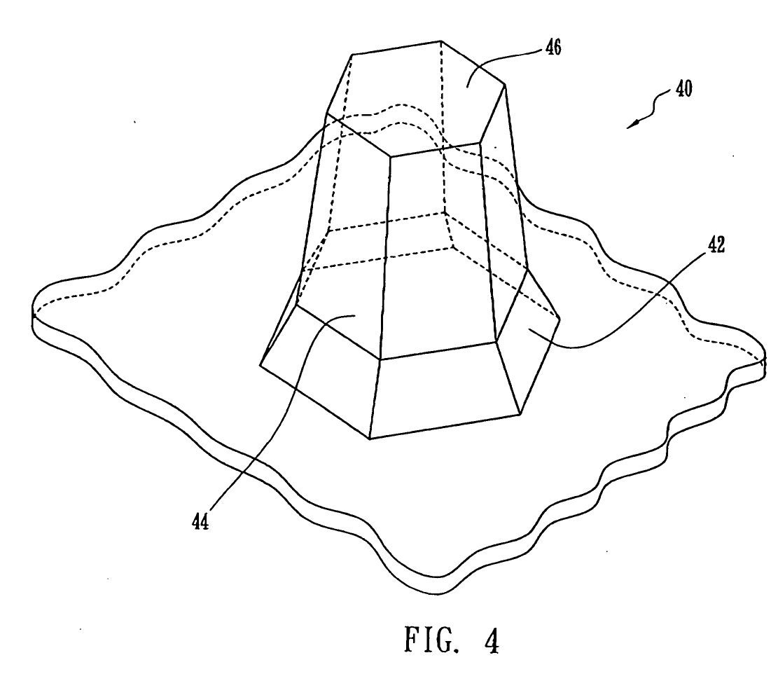

FIG. 4 illustrates a solar energy collector 40 as a symmetrically hexagonal roof according to a third embodiment of the present invention. The solar energy collector 40 includes six first rectangular plates 42 positioned on the substrate 12 in a hexagonal manner, six second rectangular plates 44 positioned on the first rectangular plates 42 in a hexagonal manner and a hexagonal plate 46 positioned on the second rectangular plates 44. Particularly, the first rectangular plates 42 and the second rectangular plates 44 are positioned on the substrate 12 in an inclined manner, and the included angle between the first rectangular plates 42 and the substrate 12 is smaller than the included angle between the second rectangular plates 44 and the substrate 12.

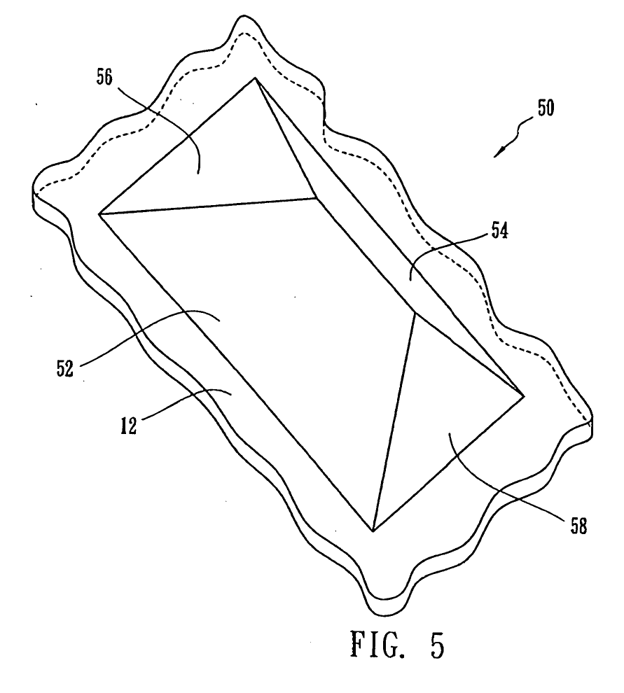

FIG. 5 illustrates a solar energy collector 50 as an asymmetrical hip roof according to a fourth embodiment of the present invention. The solar energy collector 50 includes a trapezoid plate 52, a trapezoid plate 54, a triangular plate 56, and a triangular plate 58. The trapezoid plate 52 is different from the trapezoid plate 54, the triangular plate 56 is different from the triangular plate 58, and these plates are positioned on the substrate 12 in an asymmetrical manner so as to form an asymmetrical hip roof.

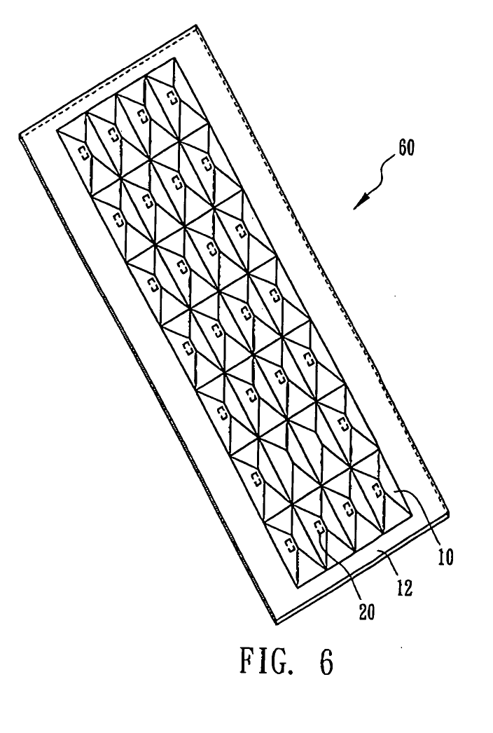

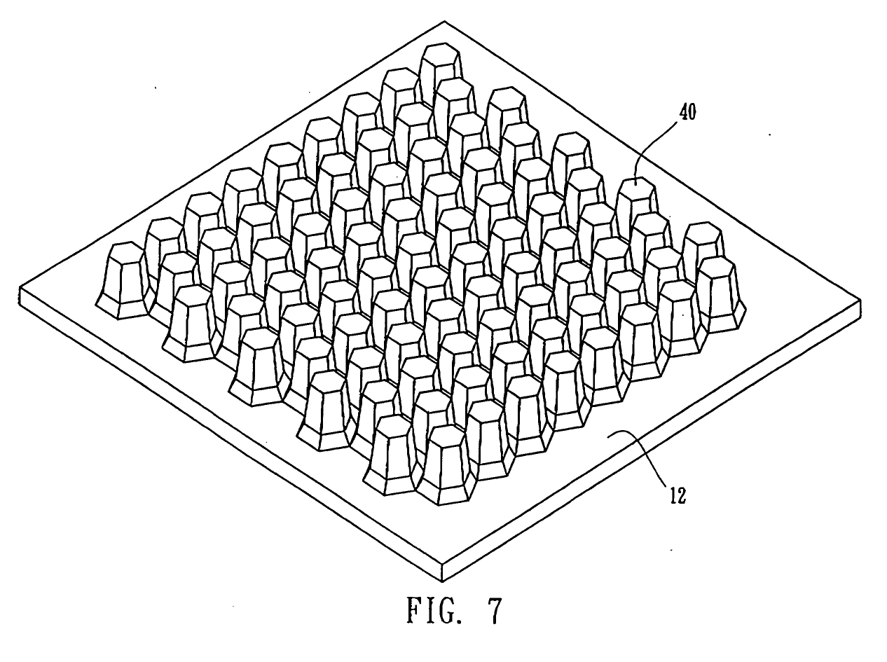

FIG. 6 illustrates a solar energy collector array 60 according to a first embodiment of the present invention. The solar energy collector array 60 includes 28 pieces of the solar energy collector 10 shown in FIG. 1, and these solar energy collectors 10 are arranged in a 7×4 array. Each solar energy collector 10 collects light beams onto its own solar cell 20. In addition, FIG. 7 illustrates another solar energy collector array 80 as a honeycomb, which consists of several solar energy collectors 40 in FIG. 4.

The conventional dome-shaped Fresnel lens is difficult to fabricate, its cost is expensive, and it is difficult for it to have a wide application. On the contrary, the present invention uses a planar plate having protrusion patterns to form a solar energy collector in a roof manner, which possesses a lower cost and can collect omni-directional light beams. Compared to the expensive fabrication of the conventional dome-shaped Fresnel lens, the fabrication cost of the present planar plate is much lower since it is planar. In addition, the present invention assembles the planar plate in a roof manner; therefore the collector can collect omni-directional light beams penetrating therethrough.

The above-described embodiments of the present invention are intended to be illustrative only. Numerous alternative embodiments may be devised by those skilled in the art without departing from the scope of the following claims.

We claim:

1. A solar energy collector, comprising:
a substrate; and
a plurality of plates assembled on the substrate in a form of a roof, wherein the plates are comprised of a plurality of protrusions capable of refracting light beams that penetrate through the plates to a predetermined position of the substrate.

2. The solar energy collector of claim 1, further comprising:
a solar cell positioned on the predetermined position of the substrate.

3. The solar energy collector of claim 1, wherein the plurality of plates are positioned on the substrate in an inclined manner.

4. The solar energy collector of claim 1, wherein the plurality of plates are positioned on the substrate in a symmetrical manner.

5. The solar energy collector of claim 4, wherein the plurality of plates are positioned on the substrate in a tetragonal manner.

6. The solar energy collector of claim 5, comprising:
two trapezoid plates positioned on the substrate in an inclined manner;
two triangular plates positioned on the substrate in an inclined manner; and
a rectangular plate positioned on the trapezoid plates and the triangular plates.

7. The solar energy collector of claim 5, further comprising
four trapezoid plates positioned on the substrate in an inclined manner; and
a rectangular plate positioned on the trapezoid plates.

8. The solar energy collector of claim 4, wherein the plurality of plates are positioned on the substrate in a hexagonal manner.

9. The solar energy collector of claim 8, comprising:
six first rectangular plates positioned on the substrate in an inclined manner;
six second rectangular plates positioned on the first rectangular plates in an inclined manner; and
a hexagonal plate positioned on the second rectangular plate.

10. The solar energy collector of claim 9, wherein an included angle between the first rectangular plates and the substrate is smaller than an included angle between the second rectangular plates and the substrate.

11. The solar energy collector of claim 1, wherein the plurality of plates are positioned on the substrate in an asymmetrical manner.

12. The solar energy collector of claim 11, comprising:
a plurality of trapezoid plates positioned on the substrate in an inclined manner; and
a plurality of triangular plates positioned on the substrate in an inclined manner.

13. A solar energy collecting array, comprising:
a substrate; and
a plurality of collecting units positioned on the substrate in an array manner, wherein the collecting units are each comprised of a plurality of plates assembled in a form of a roof, the plates having a plurality of protrusions capable of refracting light beams that penetrate through the plates to a predetermined position of the substrate.

14. The solar energy collector array of claim 13, further comprising:
a solar cell positioned on the predetermined position of the substrate.

15. The solar energy collector array of claim 13, wherein the plurality of plates are positioned on the substrate in an inclined manner.

16. The solar energy collector array of claim 13, wherein the plurality of plates are positioned on the substrate in a symmetrical manner.

17. The solar energy collector array of claim 16, wherein the plurality of plates are positioned on the substrate in a tetragonal manner.

18. The solar energy collector array of claim 17, comprising:
two trapezoid plates positioned on the substrate in an inclined manner;
two triangular plates positioned on the substrate in an inclined manner; and
a rectangular plate positioned on the trapezoid plates and the triangular plates.

19. The solar energy collector array of claim 17, comprising:
four trapezoid plates positioned on the substrate in an inclined manner; and
a rectangular plate positioned on the trapezoid plates.

20. The solar energy collector array of claim 16, wherein the plurality of plates are positioned on the substrate in a hexagonal manner.

21. The solar energy collector array of claim 20, comprising:
six first rectangular plates positioned on the substrate in an inclined manner;
six second rectangular plates positioned on the first rectangular plates in an inclined manner; and
a hexagonal plate positioned on the second rectangular plates.

22. The solar energy collector array of claim 21, wherein an included angle between the first rectangular plates and the substrate is smaller than an included angle between the second rectangular plates and the substrate.

23. The solar energy collector array of claim 13, wherein the plurality of plates are positioned on the substrate in an asymmetrical manner.

24. The solar energy collector array of claim 23, comprising:
a plurality of trapezoid plates positioned on the substrate in an inclined manner; and
a plurality of triangular plates positioned on the substrate in an inclined manner.
